(19) United States
(12) Patent Application Publication
(10) Pub. No.: US 2025/0277752 A1
(43) Pub. Date: Sep. 4, 2025

(54) OPTICAL INSPECTION SYSTEM, METHOD OF OPTICAL INSPECTION, AND METHOD OF MANUFACTURING SEMICONDUCTOR PACKAGE

(71) Applicant: Taiwan Semiconductor Manufacturing Company, Ltd., Hsinchu (TW)

(72) Inventors: Zih-Ying Yang, Hsinchu City (TW); Yang-Chih Hsueh, Hsinchu City (TW); Ming-Tsu Chung, Hsinchu (TW); Yan-Zuo Tsai, Hsinchu City (TW); Yung-Chi Lin, New Taipei City (TW)

(73) Assignee: Taiwan Semiconductor Manufacturing Company, Ltd., Hsinchu (TW)

(21) Appl. No.: 18/594,009

(22) Filed: Mar. 4, 2024

(51) Int. Cl. G01N 21/95; G01N 21/88; H01L 21/66; H01L 21/683

(52) U.S. Cl. CPC G01N 21/9501; G01N 21/8806; G01N 21/8851; H01L 21/6836; H01L 21/6838; H01L 22/12; H01L 22/26; G01N 2021/8809; G01N 2021/8841; H01L 2221/68322; H01L 2221/68327

(57) ABSTRACT

An optical inspection system includes a die carrier, a camera device, and a processor. The die carrier is configured to carry a die, wherein a backside surface of the die faces away from the die carrier. The camera device is movably disposed above the die carrier and configured to capture images of a plurality of detecting spots on the backside surface, wherein the plurality of detecting spots comprising a plurality of die corners of the die. The processor is coupled to the camera device and configured to determine a die center of the die according to the images of the plurality of die corners of the die, and determine whether the die is a bad die according to an existence of a defect on the backside surface of the die detected by the camera device.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 7 illustrate schematic views of intermediate stages in the manufacturing of a semiconductor package according to some exemplary embodiments of the present disclosure.

FIG. 8 is a diagram illustrating a relationship between wavelength and intensity of light according to some exemplary embodiments of the present disclosure.

FIG. 9 and FIG. 10 illustrate schematic views of camera devices capturing images of a plurality of detecting spots on a die according to some exemplary embodiments of the present disclosure.

FIG. 11 and FIG. 12 illustrate schematic views of camera devices capturing images of a plurality of detecting spots on a die according to some exemplary embodiments of the present disclosure.

FIG. 13 illustrates a schematic view of a camera device capturing images of a plurality of detecting spots on a die according to some exemplary embodiments of the present disclosure.

FIG. 14 illustrates a schematic view of a camera device disposed on a moving mechanism according to some exemplary embodiments of the present disclosure.

FIG. 15 illustrates a schematic view of a camera device capturing images of a plurality of detecting spots on a die according to some exemplary embodiments of the present disclosure.

FIG. 16 illustrates a schematic view of a line-scan camera device capturing images of a plurality of detecting spots on a die according to some exemplary embodiments of the present disclosure.

FIG. 17 illustrates a schematic view of a camera device disposed on a moving mechanism according to some exemplary embodiments of the present disclosure.

FIG. 18 and FIG. 19 illustrate schematic views of a camera device disposed on a moving mechanism according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The optical inspection system and methods provided in the disclosure are used to evaluate to what extent defects are present on a semiconductor die. For example, the optical inspection system can be used to optically inspect and detect tape residue, and/or particle contaminants on the surface of the die before the die is bonded to another workpiece such as a die, an interposer, a substrate, a wafer, or the like. Accordingly, some aspects of the present disclosure provide for optical inspection system and methods by which dies can be inspected in-situ with limited, if any, human handling/transport. As such, these optical inspection system and methods limit labor costs and also minimize breakage, contamination, and defects for dies and improve yields of subsequent bonding process.

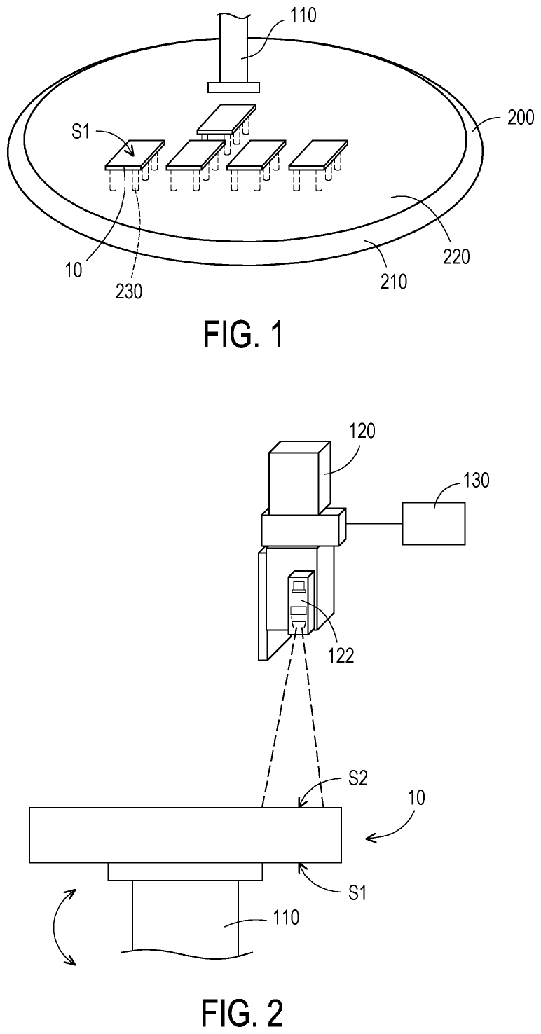

FIG. 1 to FIG. 7 illustrate schematic views of intermediate stages in the manufacturing of a semiconductor package according to some exemplary embodiments of the present disclosure. A method of manufacturing a semiconductor package may include the following steps. In some embodiments, a semiconductor wafer is provided on a tape carrier 200. For example, the tape carrier 200 includes an adhesive tape 220, which is supported and fixed to a ring flame 220. The semiconductor wafer may be press-bonded onto the adhesive tape 220 of the tape carrier 200. Referring to FIG. 1, the dicing process is performed to a plurality of scribe lines on the semiconductor wafer to form a plurality of dies 10 on the tape carrier 200. In some embodiments, the dicing process can adopt, for example, a cutting method called full-cut that forms a slit into the adhesive tape 220 of the tape carrier 200. The dicing apparatus used in the dicing process is not particularly limited, and a conventionally known apparatus can be used. Further, since the semiconductor wafer is adhered and fixed by the tape carrier 200, die crack and die fly can be suppressed, as well as the damage of the semiconductor wafer can also be suppressed. Consequently, the semiconductor wafer is cut into a prescribed size and individualized (is formed into small pieces) to from individual dies 10, i.e., semiconductor chips. In some embodiments, each of the dies 10 includes a front side surface S1, which circuits or the like of the die 10 is formed, and a backside surface S2 opposite to front side surface S1. In some embodiments, the backside surface S2 of the die 10 is attached to the tape carrier 200 while the front side surface S1 faces way from the tape carrier 200.

Then, picking-up one of the plurality of dies 10 from the tape carrier 200 is performed in order to collect a dies 10 that is adhered and fixed to the tape carrier 200 for the subsequent bonding process. For example, a pick and place tool may be used to separate the individual dies 10 from the tape carrier 200. The pick and place tool includes a die carrier 110, which is configured to pick up an individual die 10 from the tape carrier 200, carry the die 10, and place the die 10 onto a substrate such as an interposer, a package substrate, a wafer or other dies. In one embodiment, the die carrier 110 may be a vacuum collet configured to lift the die 10 from the tape carrier 200 and places it onto a substrate to be bonded. In the embodiment, the die carrier 110 picks up the die 10 with its front side surface S1 facing the die carrier 110, and the backside surface S2 faces away from the die carrier 110. In some embodiments, a plurality of ejector pins 230 are disposed underneath the tape carrier 200, and the die 10 is pushed up by the ejector pins 230, and is picked up by vacuum with the die carrier 110. In other words, the ejector pins 230 underneath the tape carrier 200 are ejected for pushing the die 10 away from the tape carrier 200.

Then, referring to both FIGS. 1 and 2, after the die 10 is picked up by the die carrier 110, the die 110 may be flipped by the die carrier 110, so that the backside surface S2 of the die 10 faces up toward a camera device 120, which is movably disposed above the die carrier 110. The camera device 120 is configured to capture images of a plurality of detecting spots on the backside surface S2 to find a die center and detect defects on the backside surface S2 of the die 10. Generally, when the die 10 is picked up from the tape carrier 200, a part of the tape residue from the tape carrier 200 may be left on the backside surface S2 of the die during the pickup process, especially at spots where the ejector pins 230 (shown in FIG. 1) pushes the backside surface S2 of the die 10. The tape residue may lead to an uneven contact surface (i.e., backside surface S2 with tape residue left thereon) pressed by a bonding head in the subsequent bonding process and causes poor bonding quality or even die crack. In addition, a part of the tape residue may even be stuck to the bonding head and then contaminates other dies. Accordingly, the disclosure provides system and method to detect defects on the backside surface S2 of the die 10 before the bonding process is performed. The defects may include tape residue, particles, contaminants, or the like, left on the backside surface S2 of the die 10.

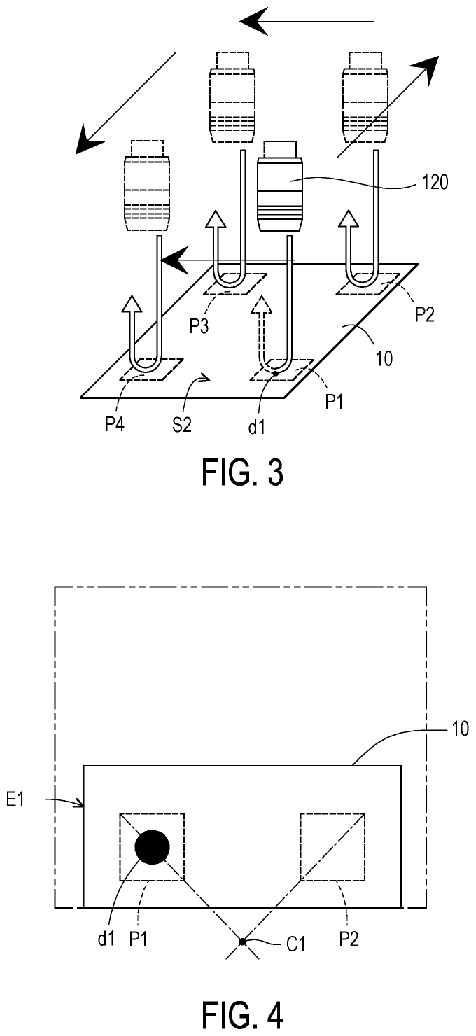

Referring to FIG. 2 and FIG. 3, in accordance with some embodiments of the disclosure, the optical inspection system include the die carrier 110, at least one camera device 120, and a processor 130 coupled to the camera device 120. The camera device 120 is configured to capture images of a plurality of detecting spots P1, P2, P3, and P4 on the backside surface S2 of the die 110. It is noted that 4 detecting spots P1, P2, P3, and P4 are illustrated in the present embodiment, but more or less detecting spots may also be applied, and the disclosure is not limited thereto. In the embodiment, one camera device 120 is adopted to capture images of the detecting spots P1, P2, P3, and P4, but in other embodiments, more camera devices may also be applied. In the present embodiment, the detecting spots P1, P2, P3, and P4 includes a plurality of die corners of the die 10. In some embodiments, the detecting spots may correspond to the spots where the ejector pins (e.g., the ejector pins 230 shown in FIG. 2) pushes backside surface S2 of the die 110, which is the spots that tape residue is most likely to occur.

Referring to FIG. 3 and FIG. 4, in the present embodiment, the camera device 120 can be mounted on a robot arm, so as to be moved above the die 10 (e.g., moved along arrows shown in FIG. 3) for capturing the images of the detecting spots P1, P2, P3, and P4, such as images of the die corners. Accordingly, the processor 130 is configured to identify the borders, edges, or boundaries of the die 10 according to the images of the die corners captured by the camera device 120. Then, the processor 130 can determine a die center C1 of the die 10 according to the identified die edges E1. The die center C1 of the die 10 can be used for the subsequent bonding process.

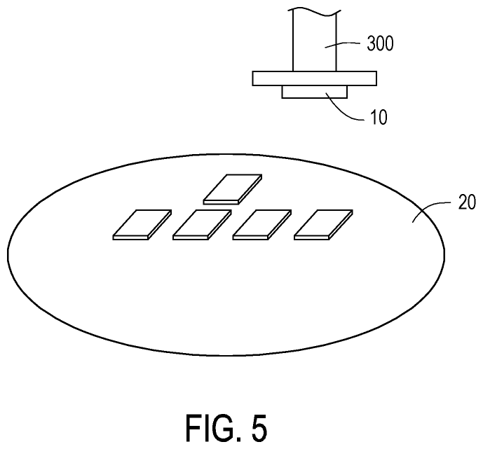

Referring to FIG. 3 to FIG. 5, in addition, the processor 130 can further determine whether the die 10 beneath the camera device 120 is a good die or a bad die in accordance with an existence of a defect d1 on the detecting spots P1, P2, P3, and P4, such that the die 10 can be selectively picked for the subsequent bonding process. In detail, the processor 130 determine whether there is any defect on the detecting spots P1, P2, P3, and P4 of the die 10. If there is no defect detected on the detecting spots P1, P2, P3, and P4, the die 10 is determined to be a good die, so the die 10 can be placed onto a bonding apparatus for the subsequent bonding process. Then, as shown in FIG. 5, the die 10 can be bonded to a substrate 20 according to the die center determined earlier. In other embodiment, the determination of the die center C1 may be performed after the die 10 is determined to be a good die. If there is a defect detected on at least one of the detecting spots P1, P2, P3, and P4, the die 10 is determined to be a bad die, so the die 10 would be skipped (not used) for the subsequent bonding process.

Referring to FIG. 2 and FIG. 3, in some embodiments, the camera device 120 includes a light source 122 for emitting light toward the die 10. The light source 122 may include an illumination source optical element such as a lens, a spectral filter, a polarizer, a diffuser, a spatial filter, a liquid crystal display, a switchable film, polymer dispersed liquid crystals, an electrochromic device, a photochromic device, a sub-combination thereof, a combination thereof, etc. The determination of existence of a defect on the detecting spots may be described as follows. In the present embodiment, the camera device 120 may be sequentially moved to the detecting spots P1, P2, P3, and P4 to respectively determine whether there is a defect on the detecting spots P1, P2, P3, and P4. For example, the camera device 120 may firstly be moved to the detecting spot P1, so that the light source 122 emits light toward the detecting spot P1. Then, an optical sensor of the camera device 120 is configured to detect an intensity of the light reflected by the detecting spot P1. In detail, the light from the light source 122 may impact the detecting spot P1 and result in regular reflections and/or diffuse reflections. The regular reflections and/or the diffuse reflections may be dependent upon, for example, any target defects. For example, a planar surface without any defect thereon may directly reflect the light and an uneven surface with defect thereon may diffuse the light.

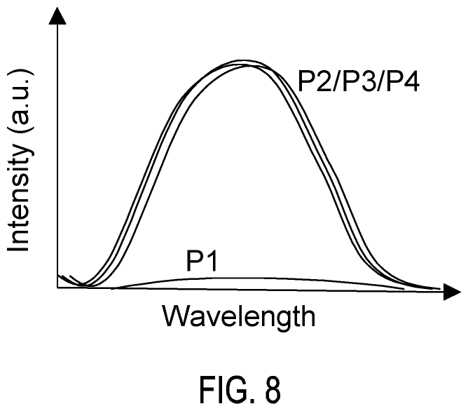

FIG. 8 is a diagram illustrating a relationship between wavelength and intensity of light according to some exemplary embodiments of the present disclosure. Referring to FIG. 3 and FIG. 8, in the present embodiment, there is a defect d1 on the detecting spot P1 as shown in FIG. 3, so more diffuse reflection may occur when the light impact the defect d1 (e.g., tape residue) on the detecting spot P1. The optical sensor of the camera device 120 is configured to detect an intensity of the light reflected by the detecting spot P1. Accordingly, the processor may determine the existence of the detect d1 by, for example, distinguishing intensity of reflection of the light associated with the detect d1 from intensity of reflection of the light associated with the detecting spots P2, P3, P4 that does not include a defect d1. For example, referring to FIG. 8, at a specific wavelength, the intensity of the light at the detecting spots P2, P3, P4 is much higher than the intensity of the light at the detecting spot P1 due to the existence of the defect d1 on the detecting spot P1. Accordingly, when the intensity of the light is less than a predetermined value, the processor 130 can determine the existence of the defect d1 on the detecting spot P1. When the processor 130 determines there is a defect d1 on any of the detecting spots P1, P2, P3, P4, the die 10 is determined to be a bad die. When the processor 130 determines there is no defect on any of the detecting spots P1, P2, P3, P4, the die 10 is determined to be a good die, and can be continued on the subsequent bonding process.

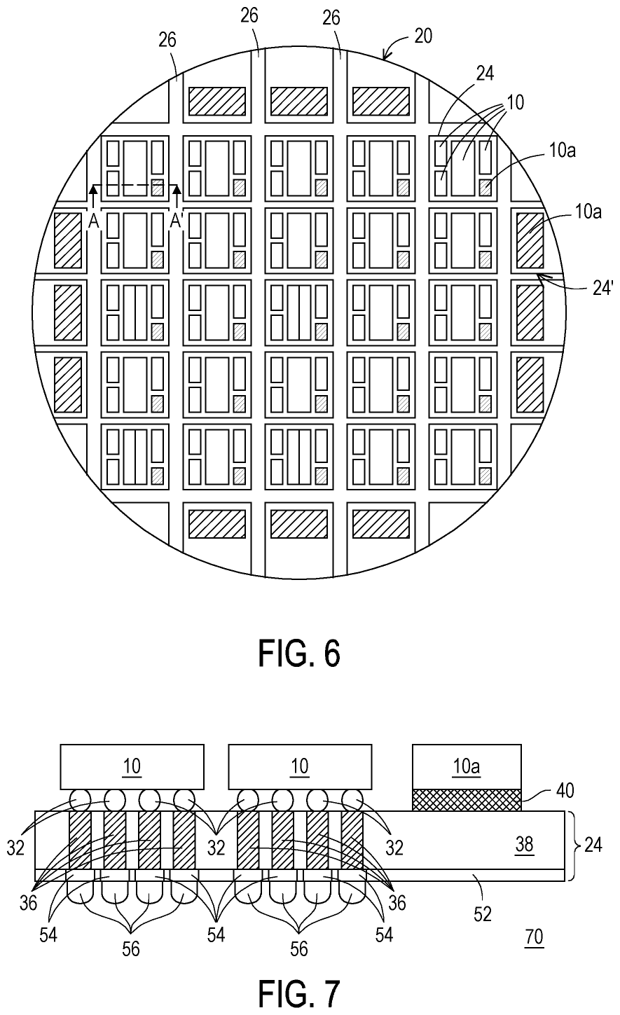

Referring to FIG. 6 and FIG. 7, in some embodiments, the dies 10 that are determined to be good dies may then be bonded to the substrate 20 one by one. During the bonding process, the pick and place tool or subsequent multi-die holder may use a thermal compression bonding head for pick and place the die 10 and then apply heat and pressure for bonding. The die 10 with array of solder bumps 32 may go through a solder reflow furnace to electrically connect the die 10 to the substrate 20. In an embodiment, the substrate 20 is a device wafer including semiconductor substrate 38 (shown in FIG. 7), and active devices such as transistors (not shown) formed at the surface of semiconductor substrate 38. The semiconductor substrate 38 may be a silicon substrate, or may be formed of other semiconductor materials. The device wafer 20 includes a plurality of identical bottom chips 24 therein. A plurality of scribe lines 26 separate the bottom chips 24 from each other. The dies 10 are bonded to the device wafer 20. In some embodiments, a plurality of dummy dies 10a may also be bonded to the device wafer 20. Throughout the description, the die 10 may be referred to “active die” or “active top die”, which is the die or chip that has electrical functions that contribute to the electrical operation of the resulting package, while the term “dummy die” refers to the die or chip that does not have any electrical function, and the dummy die does not contribute to the electrical operation of the resulting package. The dies 10 may be device dies, or may be packages that including device dies bonded to other package components such as a package substrate, an interposer, and the like.

FIG. 7 illustrates a cross-sectional view of the structure shown in FIG. 6, wherein the cross-sectional view is taken along a plane crossing line A-A′ in FIG. 6. The bottom chips 24 may be active chips that include active devices, contact plugs, metal lines, vias and the like (which are formed over top surface of the substrate 38), although they are not shown in FIG. 7. As shown in FIG. 7, the bottom chip 24 may be bonded with one or multiple dies 10 and/or one or multiple dummy dies 10a. A plurality of electrical connectors 32 bond the dies 10 and/or 10a to the bottom die 24. The electrical connectors 32 may be solder bumps, metal-to-metal bonds, solder bumps bonded to metal posts, or the like, and may be used for conducting electrical signals between the bottom chip 24 and the dies 10. Accordingly, the integrated circuit devices such as transistors (not shown) in the dies 10 are electrically coupled to the devices in the bottom chip 24. In an embodiment, the electrical connectors 32 are electrically coupled to through-substrate vias (TSVs, also sometimes known as through-silicon vias) 36 in semiconductor substrate 38. TSVs 36 extend from top surface of substrate 38 to an intermediate level between the top surface and the bottom surface of the substrate 38.

A backside interconnect structure of the bottom chip 24 (or bottom wafer 20) is formed. In an exemplary embodiment, the backside interconnect structure includes dielectric layer(s) 52, and bond pads/redistribution lines 54. Bond pads/redistribution lines 54 are electrically coupled to TSVs 36. Next, connectors 56 may be placed or formed on bond pads 54. In some embodiments, connectors 56 are solder balls or solder bumps, and are placed/formed and reflowed. In alternative embodiments, connectors 56 may include metal-to-metal bonds, solder bumps bonded to metal posts, or the like, and may be used for conducting electrical signals between bottom chip 24 and another package component such as a device die, an interposer, a package substrate, or a printed circuit board (PCB).

In one embodiment, the dummy die 10a is attached to the bottom die 24, for example, through die-attach film 40, which may be a polymer-based glue. Alternatively, the die-attach film 40 may be a thermal-plastic film that can be cured when heated. In some embodiments, the die-attach film 40 may be an adhesive that loses it adhesion when exposed under light. The dummy die 10a may be a blank die, for example, a semiconductor die (such as a silicon die) that does not have active integrated circuit devices such as transistors and/or passive devices such as resistors, capacitors, and/or the like, formed therein. The dummy die 10a may also be free from low-k dielectric layers, metal lines, vias, and/or the like, therein. In other embodiments, the dummy die 10a may be a dielectric die. In yet other embodiments, the dummy die 10 may reuse bad dies that failed in the previous tests (e.g., having defects on its backside surface), and hence may include integrated circuit devices such as transistors therein. However, the integrated circuit devices in the dummy die 10a, if any, do not perform any electrical function in the operation of the resulting semiconductor package 70, and are not supplied with power. The die-attach film 40 may be formed of an electrical insulating material, and may electrically insulate the dummy die 10a from the bottom chip 24. Although FIG. 7 illustrates a single dummy die 10a bonded to one the bottom chip 24, in alternative embodiments, a plurality of dummy dies 10a may be attached to the same bottom chip 24.

Referring back to FIG. 6, some of dummy dies 10a are attached to the bottom chips 24, which the bottom chips 24 are complete chips having a rectangular shape, and are functional chips. Additional dummy dies 10a may also be attached to incomplete bottom chips 24′. The incomplete bottom chips 24′ are located at the edges of wafer 20, and do not have rectangular shapes. The incomplete bottom chips 24′ will not be packaged as products for use. Accordingly, no active dies 10 are bonded to incomplete bottom chips 24′. The dummy dies 10a are configured to reduce issues of stress concentration and/or CTE mismatch of the semiconductor package 70.

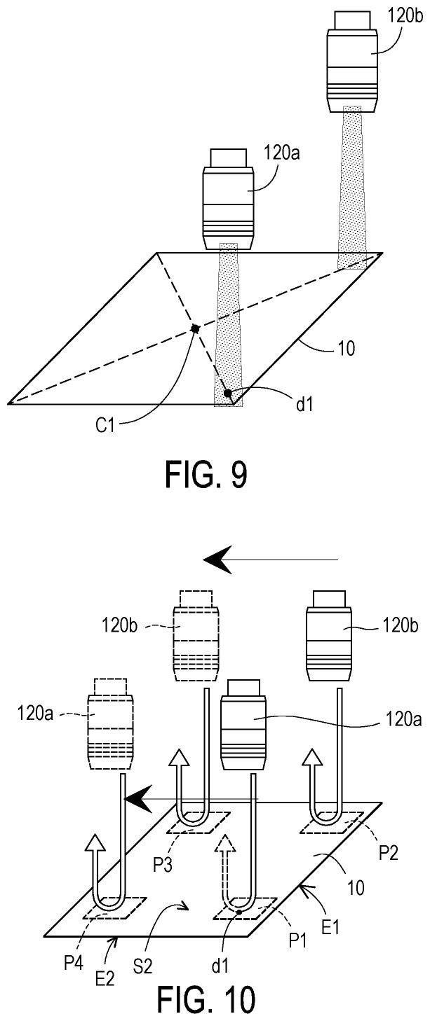

FIG. 9 and FIG. 10 illustrate schematic views of camera devices capturing images of a plurality of detecting spots on a die according to some exemplary embodiments of the present disclosure. It is noted that the optical inspection system shown in FIG. 9 and FIG. 10 contains many features same as or similar to the optical inspection system disclosed in the previous embodiments. For purpose of clarity and simplicity, detail description of same or similar features may be omitted, and the same or similar reference numbers denote the same or like components.

Referring to FIG. 9 and FIG. 10, in some embodiments, the optical inspection system may include a plurality of camera devices 120a, 120b disposed on a moving mechanism for moving above the die 10. It is noted that two camera devices 120a, 120b are illustrated herein, but less or more camera devices may be applied. In the embodiment, the camera devices 120a, 120b may be disposed on a cantilever arm, which is extended along a first direction parallel to a first edge E1 of the die 10, and the cantilever arm may be coupled to a sliding rail, which is extended along a second direction parallel to a second edge E2 of the die, and the first direction and the second direction intersected with each other. For example, at initial position, the camera devices 120a, 120b may be arranged along the first edge E1 of the die 10 to capture images of the detecting spots P1 and P2, and then the camera devices 120a, 120b are moved along the second edge E2 of the die to capture images of the detecting spots P3 and P4. With such configuration, the camera devices 120a, 120b can be moved in one dimension (e.g., linear movement along the edge E2) and capture images of the detecting spots distributed in two dimension (e.g., backside surface S2).

For example, the camera devices 120a, 120b may firstly be moved to the detecting spots P1, P2 respectively, so that the light sources of the camera devices 120a, 120b emits light toward the detecting spots P1, P2 respectively. Then, the optical sensors of the camera devices 120a, 120b are configured to detect intensity of the light reflected by the detecting spots P1, P2 respectively. In the present embodiment, there is a defect d1 on the detecting spot P1 as shown in FIG. 10, so more diffuse reflection may occur when the light impact the defect d1 (e.g., tape residue) on the detecting spot P1. The optical sensors of the camera devices 120a, 120b detect intensity of the light reflected by the detecting spots P1 and P2. Then, the camera devices 120a, 120b are moved to the detecting spots P3, P4 to perform the same detection process. Accordingly, the processor can determine the intensity of the light at the detecting spots P3, P4 is much higher than the intensity of the light at the detecting spots P1, P2 due to the existence of the defect d1 on the detecting spot P1. Accordingly, when the intensity of the light is less than a predetermined value, the processor 130 can determine the existence of the defect on the detecting spots P1 and/or P2, and the die 10 is determined to be a bad die, and would be skipped for the subsequent bonding process.

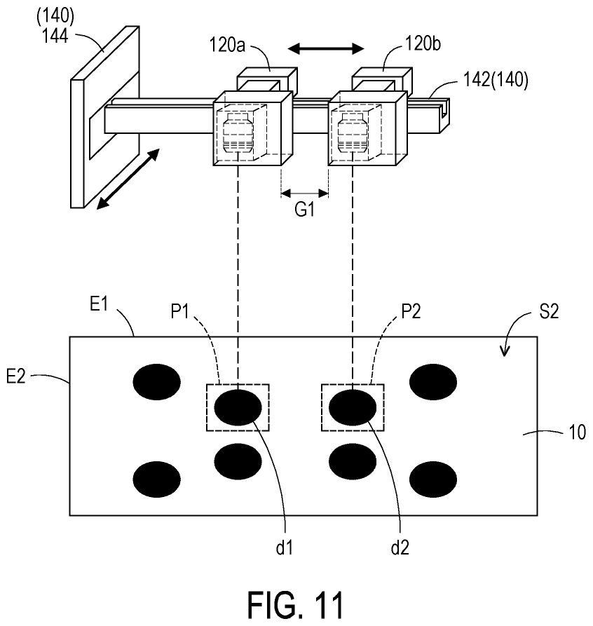

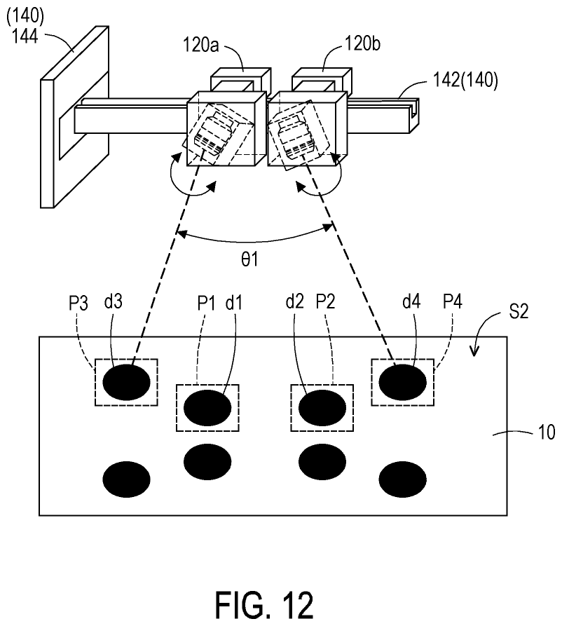

FIG. 11 and FIG. 12 illustrate schematic views of camera devices capturing images of a plurality of detecting spots on a die according to some exemplary embodiments of the present disclosure. It is noted that the optical inspection system shown in FIG. 11 and FIG. 12 contains many features same as or similar to the optical inspection system disclosed in the previous embodiments. For purpose of clarity and simplicity, detail description of same or similar features may be omitted, and the same or similar reference numbers denote the same or like components.

Referring to FIG. 11 and FIG. 12, in some embodiments, the optical inspection system may include a plurality of camera devices 120a, 120b disposed on a moving mechanism for moving above the die 10. It is noted that two camera devices 120a, 120b are illustrated herein, but less or more camera devices may be applied. In the embodiment, moving mechanism 140 includes a sliding rail 144 and a cantilever arm 142 coupled to the sliding rail 144. The camera devices 120a, 120b are disposed on the cantilever arm 142, which is extended along a first direction parallel to a first edge E1 of the die 10, and the sliding rail 144 is extended along a second direction parallel to a second edge E2 of the die. The first direction (e.g., edge E1) and the second direction (e.g., edge E2) are intersected with each other.

In the present embodiment, for example, each of the camera devices 120a, 120b is configured to be moved along the cantilever arm 142 to adjust a gap G1 between adjacent two of the camera devices 120a, 120b, so as to adjust the positions of the camera devices 120a, 120b for capturing images of the detecting spots P1, P2 respectively, as shown in FIG. 11. In addition, referring to FIG. 12, each of the camera devices 120a, 120b is configured to rotate relatively to the cantilever arm 142 to adjust an angle θ1 included between adjacent two of the camera devices 120a, 120b, so that the camera devices 120a, 120b is able to capture images of the detecting spots P3, P4 without shifting the cantilever arm 142.

In detail, the camera devices 120a, 120b may firstly be moved by the moving mechanism 140 to the location shown in FIG. 11, and the camera devices 120a, 120b can be moved along the cantilever arm 142 to adjust the gap G1 between the camera devices 120a, 120b for capturing images of the detecting spots P1, P2 respectively. The light sources of the camera devices 120a, 120b emits light toward the detecting spots P1, P2. Then, the optical sensors of the camera devices 120a, 120b are configured to detect intensity of the light reflected by the detecting spots P1, P2 respectively. The optical sensors of the camera devices 120a, 120b detect intensity of the light reflected by the detecting spots P1 and P2. Then, the camera devices 120a, 120b are rotated relatively to the cantilever arm 142 to adjust the angle 01 included between the camera devices 120a, 120b to perform the same detection process on the detecting spots P3 and P4. In the present embodiment, there are defects d1, d2, d3, d4 on the detecting spots P1, P2, P3, and P4 as shown in FIG. 11. Accordingly, when the intensity of the light is less than a predetermined value, the processor determines the existence of the defect on the detecting spots P1, P2, P3, and/or P4, so the die 10 is determined to be a bad die, and would be skipped for the subsequent bonding process.

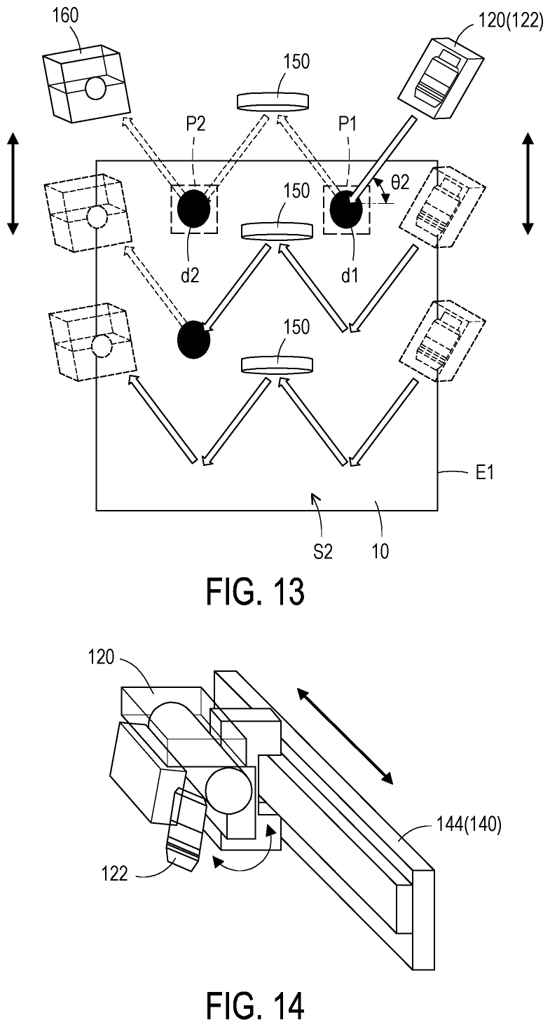

FIG. 13 illustrates a schematic view of a camera device capturing images of a plurality of detecting spots on a die according to some exemplary embodiments of the present disclosure. FIG. 14 illustrates a schematic view of a camera device disposed on a moving mechanism according to some exemplary embodiments of the present disclosure. It is noted that the optical inspection system shown in FIG. 13 and FIG. 14 contains many features same as or similar to the optical inspection system disclosed in the previous embodiments. For purpose of clarity and simplicity, detail description of same or similar features may be omitted, and the same or similar reference numbers denote the same or like components.

Referring to FIG. 13 and FIG. 14, in some embodiments, the camera device 120 is disposed on a moving mechanism 140 for moving above the die 10. In the embodiment, the camera device 120 may be coupled to a sliding rail 144, which is extended along a direction parallel to an edge E1 of the die. Accordingly, the camera device 120 can slide along the edge E1 of the die 10. In the present embodiment, the optical inspection system further includes an optical sensor 160 and a reflector 150. The optical sensor 160 and the camera device 120 are disposed on two opposite sides of the die 10 and the optical sensor 160 may be coupled to another sliding rail, which is parallel to the sliding rail 144, to slide along the opposite edge of the die 10. The reflector 150 may be a reflecting mirror and is disposed between the camera device 120 and the optical sensor 160. In the present embodiment, the optical inspection system may include a plurality of reflectors 150 arranged along the direction parallel to an edge E1 of the die. In an alternative embodiment, single reflector 150 may be coupled to a sliding rail to slide along with the camera device 120 and optical sensor 160. Accordingly, the camera device 120 includes a light source 122 for emitting light toward the die 10, the light is reflected sequentially by a first one of the detecting spots (e.g., detecting spot P1), the reflector 150, and a second one of the detecting spots (e.g., detecting spot P2), and is then detected by the optical sensor 160.

In the present embodiment, the camera device 120 is disposed at an angle θ2 with respect to the detecting spots (e.g., detecting spot P1). Accordingly, the light source 122 of the camera device 120 provides an indirect illumination source that may be configured to at least partially illuminate the detecting spots at the angle θ2 with respect to the detecting spots (e.g., detecting spot P1). The light from the light source 122 impacts the detecting spot P1 and result in direct reflections and/or diffuse reflection. As illustrated in FIG. 13, the optical sensor 160 and the reflector 150 may be geometrically oriented with respect to the light source 122 of the camera device 120, such that the reflector 150 can reflect the light reflected by one of the detecting spots and redirect the light to impact the next one of the detecting spots, and the optical sensor 160 can detect intensity of the light reflected by the next one of the detecting spots. For example, the light from the light source 122 is emitted toward the detecting spot P1, and the reflector 150 is configured to reflect the light that is reflected by the detecting spot P1 and redirected the light toward the detecting spot P2. The optical sensor 160 is configured to detect intensity of the light reflected by the detecting spot P2. Thereby, the system is capable of detecting multiple detecting spots in one direction without moving the camera device 120, so as to improve inspection efficiency.

In the present embodiment, there are defects d1, d2 at the detecting spots P1 and P2, so more diffuse reflection may occur when the light impact the defects d1, and d2 on the detecting spots P1 and P2. Accordingly, the intensity of the light at the detecting spots P1 and P2 detected by the optical sensor 160 is less than a predetermined value, so the processor 130 can determine the existence of the defects on the detecting spots P1 and/or P2, and the die 10 is determined to be a bad die, and would be skipped for the subsequent bonding process.

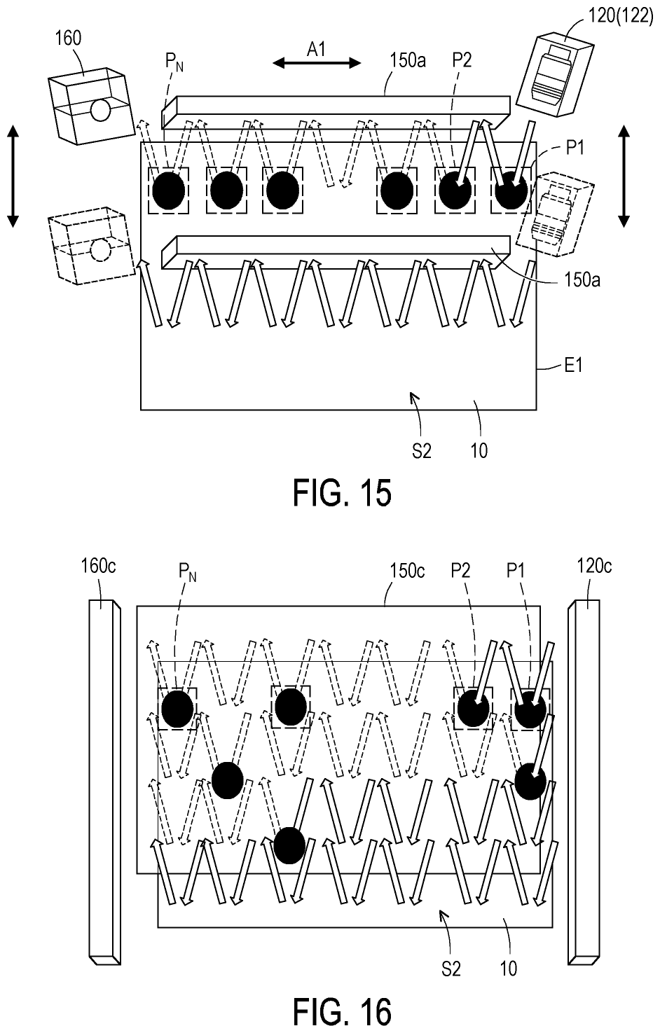

FIG. 15 illustrates a schematic view of a camera device capturing images of a plurality of detecting spots on a die according to some exemplary embodiments of the present disclosure. It is noted that the optical inspection system shown in FIG. 15 contains many features same as or similar to the optical inspection system disclosed in the previous embodiments. For purpose of clarity and simplicity, detail description of same or similar features may be omitted, and the same or similar reference numbers denote the same or like components.

Referring to FIG. 15, in some embodiments, the camera device 120 may be coupled to the sliding rail for moving along a direction parallel to the edge E1 of the die. In the present embodiment, the optical inspection system further includes an optical sensor 160 and a reflector 150. The optical sensor 160 and the camera device 120 are disposed on two opposite sides of the die 10 and the optical sensor 160 is also coupled to a sliding rail to slide along the opposite edge of the die 10. The reflector 150 is disposed between the camera device 120 and the optical sensor 160. In the present embodiment, the optical inspection system may include a plurality of line reflectors 150a parallel to one another, and the long axis A1 of each of the line reflectors 150a is perpendicular to the edge E1 of the die 10. Accordingly, the camera device 120 includes the light source 122 for emitting light toward the die 10, the light is reflected alternately between the detecting spots P1, P2 . . . , PN and the reflector, and is then detected by the optical sensor 160.

In the present embodiment, the camera device 120 is disposed at an acute angle) (<90°) with respect to the detecting spots (e.g., detecting spot P1). The light from the light source 122 impacts the detecting spot P1 and result in direct reflections and/or diffuse reflection. As illustrated in FIG. 15, the optical sensor 160 and the reflector 150a may be geometrically oriented with respect to the light source 122 of the camera device 120, such that the reflector 150a can reflect the light reflected by one of the detecting spots and redirect the light to impact the adjacent one of the detecting spots, and the optical sensor 160 can detect intensity of the light reflected by the last one of the detecting spots in the corresponding row. For example, the light from the light source 122 is emitted toward the detecting spot P1, and the reflector 150a is configured to reflect the light that is reflected by the detecting spot P1 and redirected the light toward the detecting spot P2, and the light would be reflected back and forth between the reflector 150a and the detecting spots of the die 10 until the light is received by the optical sensor 160. The optical sensor 160 detects intensity of the light reflected by the detecting spot PN. The camera device 120 can be moved to the next location (illustrated in dotted line) to detecting multiple detecting spots in the next row. Thereby, the system is capable of detecting multiple detecting spots P1, P2 . . . , PN in one row without moving the camera device 120, so as to improve inspection efficiency.

In the present embodiment, there are defects on at least the detecting spots P1, P2, and PN so more diffuse reflection may occur when the light impact the defects on those detecting spots. Accordingly, the intensity of the light at those detecting spots detected by the optical sensor 160 is less than a predetermined value, so the processor 130 can determine the existence of the defects on the detecting spots P1, P2 . . . , and/or PN, and the die 10 is determined to be a bad die, and would be skipped for the subsequent bonding process.

FIG. 16 illustrates a schematic view of a line-scan camera device capturing images of a plurality of detecting spots on a die according to some exemplary embodiments of the present disclosure. It is noted that the optical inspection system shown in FIG. 16 contains many features same as or similar to the optical inspection system disclosed in the previous embodiments. For purpose of clarity and simplicity, detail description of same or similar features may be omitted, and the same or similar reference numbers denote the same or like components.

Referring to FIG. 16, in some embodiments, the camera device may be a line-scan camera device 120c extended along an edge E1 of the die 10, the optical sensor 160c includes an array of optical sensors 160c arranged along a direction parallel to the edge E1 of the die 10, and the reflector 150c may be a plane reflector. In the embodiment, the array of optical sensors 160c may be integrated as a line-scan optical sensor. The plane reflector 150c is disposed between the line-scan camera device 120c and the array of optical sensors 160c. Accordingly, the line-scan camera device 120c includes the light source 122 for emitting light toward the die 10, the light is reflected alternately between the detecting spots P1, P2 . . . , PN and the plane reflector 150c, and is then detected by the array of the optical sensors 160c.

In the present embodiment, the line-scan camera device 120c is disposed at an acute angle (<90°) with respect to the detecting spots P1, P2 . . . , PN. As illustrated in FIG. 16, the array of the optical sensors 160c and the plane reflector 150c may be geometrically oriented with respect to the light source 122 of the line-scan camera device 120c, such that the plane reflector 150c can reflect the light reflected by one of the detecting spots and redirect the light to impact the adjacent one of the detecting spots, and the array of the optical sensors 160c can detect intensity of the light reflected by the last one of the detecting spots in the corresponding row. For example, the light from the light source 122 is emitted toward the detecting spot P1, and the plane reflector 150c is configured to reflect the light that is reflected by the detecting spot P1 and redirected the light toward the detecting spot P2, and the light would be reflected back and forth between the plane reflector 150c and the detecting spots of the die 10 until the light is received by the array of the optical sensors 160c. The array of the optical sensors 160 detect intensity of the light reflected by the detecting spot PN. Thereby, the system is capable of detecting multiple detecting spots P1, P2 . . . , PN distributed over the backside surface S2 all at once without moving the line-scan camera device 120c, so as to improve inspection efficiency.

In the present embodiment, there are defects on at least the detecting spots P1, P2, and PN so more diffuse reflection may occur when the light impact the defects on those detecting spots. Accordingly, the intensity of the light at those detecting spots detected by the array of the optical sensors 160c is less than a predetermined value, so the processor can determine the existence of the defects on the detecting spots P1, P2 . . . , and/or PN, and the die 10 is determined to be a bad die, and would be skipped for the subsequent bonding process.

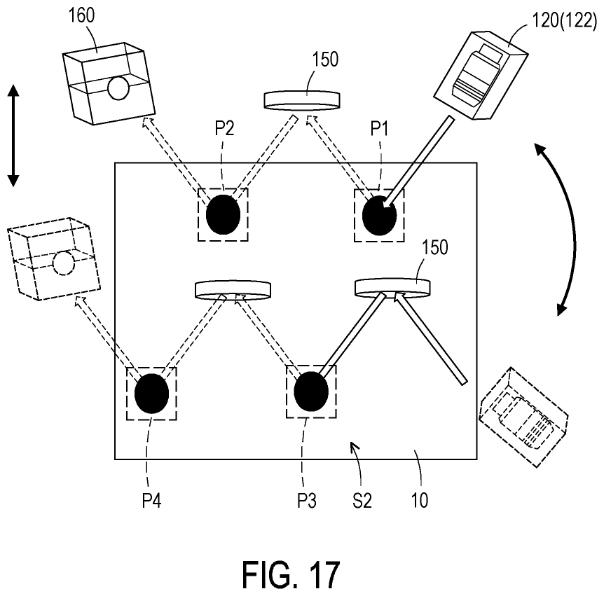

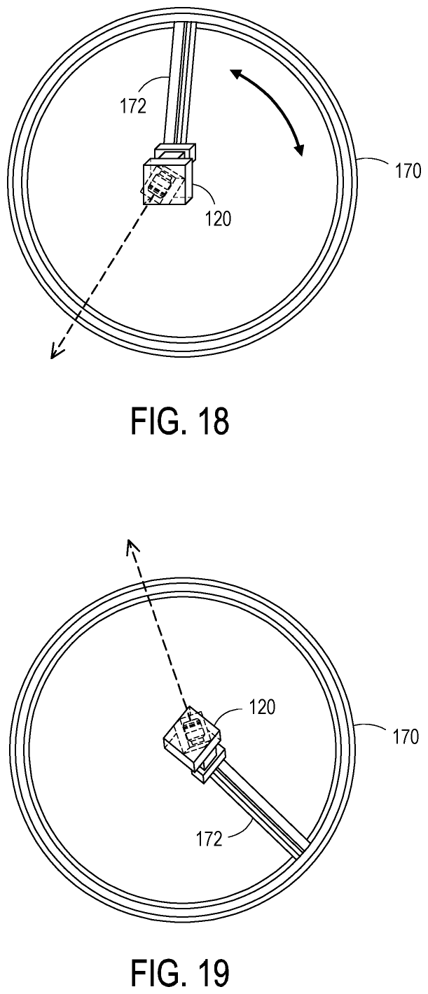

FIG. 17 illustrates a schematic view of a camera device disposed on a moving mechanism according to some exemplary embodiments of the present disclosure. FIG. 18 and FIG. 19 illustrate schematic views of a camera device disposed on a moving mechanism according to some exemplary embodiments of the present disclosure. It is noted that the optical inspection system shown in FIG. 17 to FIG. 19 contains many features same as or similar to the optical inspection system disclosed in the previous embodiments. For purpose of clarity and simplicity, detail description of same or similar features may be omitted, and the same or similar reference numbers denote the same or like components.

Referring to FIG. 17 to FIG. 19, in some embodiments, the camera device 120 is movably disposed on a ring sliding rail 170 at a side of the die 10 for changing a light emitting direction (angle) of the light emitted by the light source 122. In the present embodiment, the ring sliding rail 170 may further include a cantilever arm 172 extended toward the die 10. The optical sensor 160 and the camera device 120 are disposed on two opposite sides of the die 10 and the optical sensor 160 may be coupled to a linear sliding rail to slide along an edge of the die 10. That is, the optical sensor 160 and the camera device 120 are disposed on two opposite sides of the die 10, but the camera device 120 is configured to rotate relatively to the die 10 while the optical sensor 160 is configured to slide along the edge of the die 10. In one embodiment, the ring sliding rail 170 may further be moved along the edge of the die 10 by, for example, coupled to a linear sliding rail extended along the edge of the die 10. The reflectors 150 are disposed between the camera device 120 and the optical sensor 160, and are geometrically oriented with respect to the light source 122 of the camera device 120, such that the reflector 150 can reflect the light reflected by the detecting spots and redirect the light to impact the adjacent one of the detecting spots, and the optical sensor 160 can detect intensity of the light reflected by the last one of the detecting spots in the corresponding row.

In the present embodiment, when the camera device 120 is located at the first position where the camera device 120 is illustrated in solid line in FIG. 17 and also shown in FIG. 18, the light from the light source 122 is emitted downward at an acute angle) (<90°) with respect to the detecting spot P1. The light from the light source 122 impacts the detecting spot P1 and result in direct reflections and/or diffuse reflection. The reflector 150 can reflect the light reflected by the detecting spot P1 and redirect the light to impact the adjacent one of the detecting spots (e.g., the detecting spot P2), and the optical sensor 160 can detect intensity of the light reflected by the detecting spot P2. Then, the camera may be rotated along the ring sliding rail 170 to a second position where the camera device 120 is illustrated in dotted line in FIG. 17 and also shown in FIG. 19, the light from the light source 122 is emitted upward at an acute angle (<90°) with respect to the reflector 150. The light from the light source 122 impacts the reflector 150 and is reflected and redirected toward the detecting spot P3, and may be reflected and redirected again by the next reflector to impact the detecting spots P4, so the optical sensor 160 can detect intensity of the light reflected by the detecting spot P4. Thereby, the location of the detecting spots and the gap between the detecting spots may be adjusted by rotating the camera device 120 to change the incident angle of the light, so as to improve inspection flexibility.

In the present embodiment, there are defects on the detecting spots P1, P2, P3, and P4, so more diffuse reflection may occur when the light impact the defects on those detecting spots. Accordingly, the intensity of the light at those detecting spots detected by the optical sensor 160 is less than a predetermined value, so the processor can determine the existence of the defects on the detecting spots P1, P2, P3, and/or P4, and the die 10 is determined to be a bad die, and would be skipped for the subsequent bonding process.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, an optical inspection system includes a die carrier, a camera device, and a processor. The die carrier is configured to carry a die, wherein a backside surface of the die faces away from the die carrier. The camera device is movably disposed above the die carrier and configured to capture images of a plurality of detecting spots on the backside surface, wherein the plurality of detecting spots comprising a plurality of die corners of the die. The processor is coupled to the camera device and configured to determine a die center of the die according to the images of the plurality of die corners of the die, and determine whether the die is a bad die according to an existence of a defect on the backside surface of the die detected by the camera device. In one embodiment, the camera device comprises a plurality of camera devices arranged along a cantilever arm, which is configured to be moved along a sliding rail. In one embodiment, the cantilever arm is extended along a first direction parallel to a first edge of the die and the sliding rail is extended along a second direction parallel to a second edge of the die, and the first direction and the second direction intersected with each other. In one embodiment, each of the plurality of camera devices is configured to be moved along the cantilever arm to adjust a gap between adjacent two of the plurality of camera devices and rotated relatively to the cantilever arm to adjust an angle included between adjacent two of the plurality of camera devices. In one embodiment, the optical inspection system further includes an optical sensor and a reflector disposed between the camera device and the optical sensor, wherein the camera device comprises a light source for emitting light toward the die, the light is reflected sequentially by a first one of the plurality of detecting spots, the reflector, and a second one of the plurality of detecting spots, and is then detected by the optical sensor. In one embodiment, the reflector comprises a plurality of reflectors arranged along a direction parallel to an edge of the die. In one embodiment, the reflector comprises a plurality of line reflectors parallel to one another, and a long axis of each of the plurality of line reflectors is perpendicular to an edge of the die. In one embodiment, the processor determines the existence of a defect when an intensity of the light detected by the optical sensor is less than a predetermined value. In one embodiment, the camera device is coupled to a first sliding rail extended along an edge of the die and the optical sensor is coupled to a second sliding rail parallel to the first sliding rail. In one embodiment, the camera device comprises a line-scan camera device extended along an edge of the die, the optical sensor comprises an array of optical sensor arranged along a direction parallel to the edge of the die, and the reflector comprises a plane reflector. In one embodiment, the camera device is movably disposed on a ring sliding rail at a side of the die for changing a light emitting direction of the light emitted by the light source. In one embodiment, the ring sliding rail is configured to be moved along an edge of the die and the optical sensor is configured to be moved along a direction parallel to the edge of the die.

In accordance with some embodiments of the disclosure, a method of optical inspection includes the following steps: picking up a die from a tape carrier; flipping the die so that a backside surface of the die faces a camera device; capturing images of a plurality of detecting spots on the backside surface of the die by the camera device, wherein the plurality of detecting spots comprising a plurality of die corners of the die; and determining whether the die is a bad die or not according to an existence of a defect on the plurality of detecting spots of the die; and determining a die center of the die according to the images of the plurality of die corners of the die. In one embodiment, the defect comprises tape residue left on the backside surface of the die. In one embodiment, picking up the die from the tape carrier comprises ejecting a plurality of ejector pins underneath the tape carrier for pushing the die away from the tape carrier, and the plurality of detecting spots corresponding to spots where the plurality of ejector pins pushes the die. In one embodiment, determining whether the die is bad die or not according to the existence of the defect on the plurality of detecting spots of the die comprises: emitting light toward one of the plurality of detecting spots; detecting an intensity of the light reflected by the one of the plurality of detecting spots; determining the defect existing on the one of the plurality of detecting spots when the intensity of the light is less than a predetermined value; and determining the die is bad die when the defect existing on the one of the plurality of detecting spots is determined. In one embodiment, determining whether the die is bad die or not according to the existence of the defect on the plurality of detecting spots of the die comprises: emitting light toward a first one of the plurality of detecting spots, wherein the light reflected by the first one of the plurality of detecting spots is reflected and redirected toward a second one of the plurality of detecting spots by a reflector; detecting an intensity of the light reflected by the second one of the plurality of detecting spots; determining the defect existing on the first one or the second one of the plurality of detecting spots when the intensity of the light is less than a predetermined value; and determining the die is bad die when the defect existing on the first one or the second one of the plurality of detecting spots is determined.

In accordance with some embodiments of the disclosure, a method of manufacturing a semiconductor package includes the following steps: performing a dicing process to form a plurality of dies on a tape carrier; picking up one of the plurality of dies from the tape carrier; flipping the die so that a backside surface of the die faces a camera device; capturing images of a plurality of detecting spots on the backside surface of the die by the camera device; and determining the die is good die when there is no defect detected on the plurality of detecting spots of the die; determining a die center of the die according to the images of the plurality of detecting spots; and performing a bonding process for bonding the die to a substrate according to the die center. In one embodiment, the plurality of detecting spots comprising a plurality of die corners of the die, and the die center of the die is determined according to the images of the plurality of die corners of the die. In one embodiment, the method further comprising determining the die is bad die when there is a defect detected on one of the plurality of detecting spots of the die, and skipping the die for the bonding process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical inspection system, comprising:
a die carrier configured to carry a die, wherein a backside surface of the die faces away from the die carrier;
a camera device movably disposed above the die carrier and configured to capture images of a plurality of detecting spots on the backside surface, wherein the plurality of detecting spots comprising a plurality of die corners of the die; and
a processor coupled to the camera device and configured to determine a die center of the die according to the images of the plurality of die corners of the die, and determine whether the die is a bad die according to an existence of a defect on the backside surface of the die detected by the camera device.

2. The optical inspection system as claimed in claim 1, wherein the camera device comprises a plurality of camera devices arranged along a cantilever arm, which is configured to be moved along a sliding rail.

3. The optical inspection system as claimed in claim 2, wherein the cantilever arm is extended along a first direction parallel to a first edge of the die and the sliding rail is extended along a second direction parallel to a second edge of the die, and the first direction and the second direction intersected with each other.

4. The optical inspection system as claimed in claim 2, wherein each of the plurality of camera devices is configured to be moved along the cantilever arm to adjust a gap between adjacent two of the plurality of camera devices and rotated relatively to the cantilever arm to adjust an angle included between adjacent two of the plurality of camera devices.

5. The optical inspection system as claimed in claim 1, further comprises an optical sensor and a reflector disposed between the camera device and the optical sensor, wherein the camera device comprises a light source for emitting light toward the die, the light is reflected sequentially by a first one of the plurality of detecting spots, the reflector, and a second one of the plurality of detecting spots, and is then detected by the optical sensor.

6. The optical inspection system as claimed in claim 5, wherein the reflector comprises a plurality of reflectors arranged along a direction parallel to an edge of the die.

7. The optical inspection system as claimed in claim 5, wherein the reflector comprises a plurality of line reflectors parallel to one another, and a long axis of each of the plurality of line reflectors is perpendicular to an edge of the die.

8. The optical inspection system as claimed in claim 5, wherein the processor determines the existence of a defect when an intensity of the light detected by the optical sensor is less than a predetermined value.

9. The optical inspection system as claimed in claim 5, wherein the camera device is coupled to a first sliding rail extended along an edge of the die and the optical sensor is coupled to a second sliding rail parallel to the first sliding rail.

10. The optical inspection system as claimed in claim 5, wherein the camera device comprises a line-scan camera device extended along an edge of the die, the optical sensor comprises an array of optical sensor arranged along a direction parallel to the edge of the die, and the reflector comprises a plane reflector.

11. The optical inspection system as claimed in claim 5, wherein the camera device is movably disposed on a ring sliding rail at a side of the die for changing a light emitting direction of the light emitted by the light source.

12. The optical inspection system as claimed in claim 11, wherein the ring sliding rail is configured to be moved along an edge of the die and the optical sensor is configured to be moved along a direction parallel to the edge of the die.

13. A method of optical inspection, comprising:
picking up a die from a tape carrier;
flipping the die so that a backside surface of the die faces a camera device;
capturing images of a plurality of detecting spots on the backside surface of the die by the camera device, wherein the plurality of detecting spots comprising a plurality of die corners of the die; and
determining whether the die is a bad die or not according to an existence of a defect on the plurality of detecting spots of the die; and
determining a die center of the die according to the images of the plurality of die corners of the die.

14. The method as claimed in claim 13, wherein the defect comprises tape residue left on the backside surface of the die.

15. The method as claimed in claim 13, wherein picking up the die from the tape carrier comprises ejecting a plurality of ejector pins underneath the tape carrier for pushing the die away from the tape carrier, and the plurality of detecting spots corresponding to spots where the plurality of ejector pins pushes the die.

16. The method as claimed in claim 13, wherein determining whether the die is bad die or not according to the existence of the defect on the plurality of detecting spots of the die comprises:
emitting light toward one of the plurality of detecting spots;
detecting an intensity of the light reflected by the one of the plurality of detecting spots;
determining the defect existing on the one of the plurality of detecting spots when the intensity of the light is less than a predetermined value; and
determining the die is bad die when the defect existing on the one of the plurality of detecting spots is determined.

17. The method as claimed in claim 13, wherein determining whether the die is bad die or not according to the existence of the defect on the plurality of detecting spots of the die comprises:
emitting light toward a first one of the plurality of detecting spots, wherein the light reflected by the first one of the plurality of detecting spots is reflected and redirected toward a second one of the plurality of detecting spots by a reflector;
detecting an intensity of the light reflected by the second one of the plurality of detecting spots;
determining the defect existing on the first one or the second one of the plurality of detecting spots when the intensity of the light is less than a predetermined value; and
determining the die is bad die when the defect existing on the first one or the second one of the plurality of detecting spots is determined.

18. A method of manufacturing a semiconductor package, comprising:
performing a dicing process to form a plurality of dies on a tape carrier;
picking up one of the plurality of dies from the tape carrier;
flipping the die so that a backside surface of the die faces a camera device;
capturing images of a plurality of detecting spots on the backside surface of the die by the camera device; and
determining the die is good die when there is no defect detected on the plurality of detecting spots of the die;
determining a die center of the die according to the images of the plurality of detecting spots; and
performing a bonding process for bonding the die to a substrate according to the die center.

19. The method as claimed in claim 18, wherein the plurality of detecting spots comprising a plurality of die corners of the die, and the die center of the die is determined according to the images of the plurality of die corners of the die.

20. The method as claimed in claim 18, further comprising determining the die is bad die when there is a defect detected on one of the plurality of detecting spots of the die, and skipping the die for the bonding process.
